(19) United States
(12) Patent Application Publication
(10) Pub. No.: US 2010/0159405 A1
(43) Pub. Date: Jun. 24, 2010

(54) METHOD OF MANUFACTURING STRUCTURE AND METHOD OF MANUFACTURING INK JET HEAD

(75) Inventors: Hiroe Ishikura, Kawasaki-shi (JP); Takumi Suzuki, Yokohama-shi (JP); Tamaki Sato, Kawasaki-shi (JP); Hirono Naito, Naka-gun (JP); Masafumi Morisue, Tokyo (JP); Yoshikazu Saito, Kawasaki-shi (JP); Ryoji Kanri, Zushi-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/634,214

(22) Filed: Dec. 9, 2009

(30) Foreign Application Priority Data
Dec. 19, 2008 (JP) 2008-323675

(51) Int. Cl. G03F 7/20; C08F 2/46

(52) U.S. Cl. 430/326; 427/487

(57) ABSTRACT

According to the fine pattern manufacturing method of the invention, the residue of a pattern which is obtained by pressing a mold is prevented from occurring, so that the structure can be more easily manufactured.

### BACKGROUND OF THE INVENTION

1. Field of the Invention

The present invention relates to a method of forming a structure and a method of manufacturing an ink jet head.

2. Description of the Related Art

In recent years, a transfer technique of a fine pattern has been proposed that is called an imprint method. An example of the imprint method is described in the following document. S. Y. Chou et al., “Nanoimprint lithography”, J. Vac. Sci. Technol. B 14(6), November/December 1996, pp. 4129-4133.

In addition, another imprint method is disclosed in the following document. T. Bailey et al., “Step and flash imprint lithography: Template surface treatment and defect analysis”, J. Vac. Sci. Technol. B 18(6), November/December 2000, pp. 3572-3577. The methods disclosed in the above-mentioned two documents relate to a mechanical machining method performed on a resist. Therefore, a residue of the resist is invariably generated on a pressed region in a mold. The residue needs to be removed by a method such as dry etching. However, due to the etching, there is a problem in that the shape of a resist pattern may be degraded or the controllability of the dimensions is reduced. In addition, in order to remove the residue while a necessary line width and the shape of the pattern are secured as much as possible, an etching method with high anisotropy is employed, so that the etching process takes a long time.

For example, in U.S. Pat. No. 6,334,960, there is disclosed a method of removing the residue after imprinting by exposure under an environment selected from among argon ions, fluorine-containing plasma, reactive ion etching gas, and a mixture thereof. In addition, in Japanese Patent Application Laid-Open No. 2003-272998, Japanese Patent Application Laid-Open No. 2004-304097, and Japanese Patent Application Laid-Open No. 2005-354017, the following methods are disclosed. There are proposed imprinting methods in which a light blocking film or a light blocking portion is formed on a convex portion of a quartz mold, and irradiating light is selectively irradiated to a negative photosensitive resin in a state where the mold is pressed against the negative photosensitive resin, and thereafter, the negative photosensitive resin is developed, so that a residue of the mold convex portion has the light blocking film is removed by the development. However, in these methods, since quartz is used for the mold, the apparatus for machining the mold is very expensive, so that the investment in the facility is increased. In addition, in order to provide the light blocking film on the convex portion of the mold, the manufacturing process of the mold is complicated.

In addition, in Japanese Patent Application Laid-Open No. 2007-207913, there is disclosed a method of removing a residue of the resist pattern in which a surface of a glass substrate on which a resist pattern is formed is electrically charged with a positive polarity, and the glass substrate and the surface of the resist pattern are irradiated by a glass cluster ionized beam. However, in this method, a new apparatus such as a glass cluster ion irradiating apparatus is needed. In addition, like the imprint method, when the residue is in a film shape, it is difficult to selectively remove only the residue film.

### SUMMARY OF THE INVENTION

An object of the present invention is to prevent a residue of a pattern which is obtained by pressing a mold from occurring so as to manufacture a structure with more convenience.

The manufacturing method of a structure according to an example of the invention includes: (1) preparing a substrate which is provided with a resin film including a positive photosensitive resin on a surface thereof; (2) coating a negative photosensitive resin, which is compatible with the positive photosensitive resin, on the resin film including the positive photosensitive resin; (3) pressing a mold formed with a pattern to the negative photosensitive resin, compatibilizing the positive photosensitive resin and the negative photosensitive resin which are provided between a convex portion of the pattern of the mold and the substrate, to form a compatible layer; (4) irradiating the entire surface of the negative photosensitive resin and the positive photosensitive resin with an active energy ray through the substrate and the mold in a state where the mold is pressed against the negative photosensitive resin to cure the negative photosensitive resin, and solubilizing the positive photosensitive resin and the compatible layer with respect to a developer; (5) releasing the mold, forming a pattern on the negative photosensitive resin, and attaching the negative photosensitive resin formed with the pattern to another support substrate; (6) peeling off only the substrate of the substrate provided with the resin film including the positive photosensitive resin from the positive photosensitive resin and the compatible layer; and (7) removing the positive photosensitive resin and the compatible layer by a developer.

According to the fine pattern manufacturing method of the invention, the residue is prevented from occurring, so that the structure can be more easily manufactured.

Further features of the present invention will become apparent from the following description of exemplary embodiments with reference to the attached drawings.

### BRIEF DESCRIPTION OF THE DRAWINGS

FIG. 1 is a perspective view illustrating an example of an ink jet head which is manufactured by a manufacturing method of an ink jet head according to the invention.

FIG. 2 is a diagram schematically illustrating a cross section of an example of an ink jet head which is manufactured by a manufacturing method of an ink jet head according to the invention.

FIGS. 3A, 3B, 3C, 3D, 3E, and 3F are diagrams schematically illustrating an example of an embodiment of a fine pattern manufacturing method according to the invention and cross sections of a substrate in Example 1.

FIGS. 4A, 4B, 4C, 4D, 4E, and 4F are diagrams schematically illustrating cross sections of a substrate in Example 2.

FIGS. 5A, 5B, 5C, 5D, 5E, and 5F are diagrams schematically illustrating an example of an embodiment of a manufacturing method of an ink jet head according to the invention and cross sections of a substrate in Example 3.

### DESCRIPTION OF THE EMBODIMENTS

In the following, embodiments of the invention will be described.

Hereinafter, the forming method of a structure according to the invention will be described in detail using a fine pattern manufacturing method as an example.

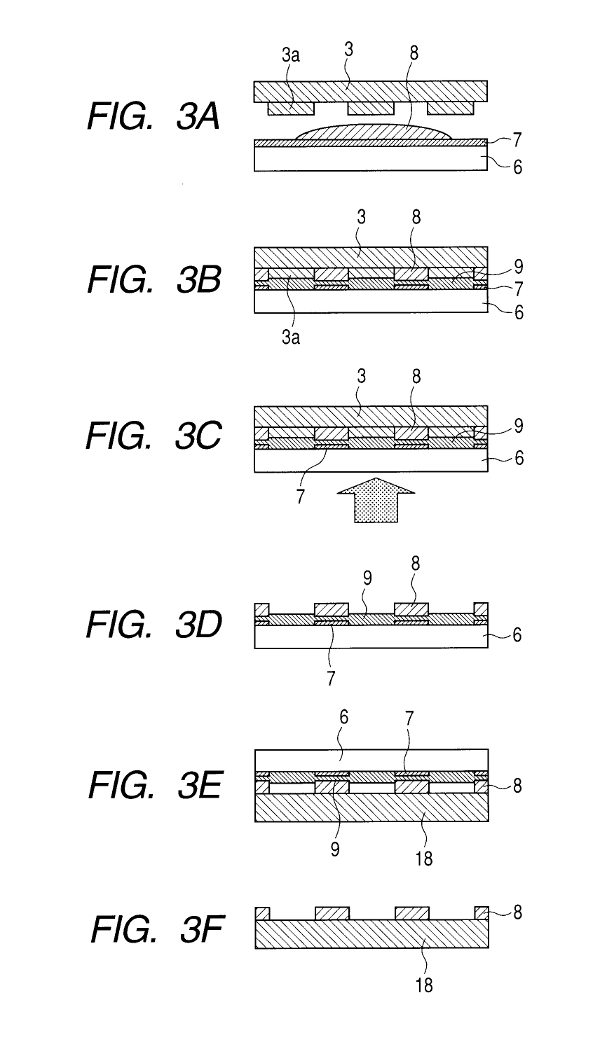

FIGS. 3A to 3F illustrate an example of an embodiment of the fine pattern manufacturing method according to the invention. Further, the invention is not limited to the following embodiment.

In this embodiment, a quartz substrate 6 is first prepared.

The substrate can be freely used without being particularly limited to a shape or material as long as the substrate serves as a support body for forming the fine pattern. In the invention, quartz must be used as the substrate as long as the mold is not a transparent material to be described later. On the other hand, when the mold is a transparent material and a material allowing an active energy ray to be described later to pass through, an opaque substrate such as silicon may be used as the substrate. In this embodiment, a quartz substrate 6 is employed as the substrate.

The surface of the quartz substrate 6 is coated with a positive photosensitive resin 7.

The positive photosensitive resin 7 of the invention is not particularly limited as long as the photosensitive resin is a positive resist which can be dissolved in a developer by being irradiated with the active energy ray. Preferably, vinyl ketone or acrylic-based photo-degradable polymer compounds such as polymethyl isopropenyl ketone and polyvinylketone may be employed.

In addition, in the invention, the positive photosensitive resin 7 contains a basic substance. This is favorable because the polymerization initiator function of the negative photosensitive resin 8 and the compatible layer 9 to be described later is inhibited. As a contained basic substance, the following may be suitably used triphenylamine, triethanolamine, triisopropanolamine, N,N-diethyl-3-aminophenol, N-ethyldiethanolamine, tertiary amines such as 2-diethylaminoethanol, diethanolamine, diisopropanolamine, secondary amines such as N-methylbenzylamine, pyrimidine, pyrimidine compounds such as 2-Aminopyrimidine, 4-aminopyrimidine, and 5-Aminopyrimidine and derivatives thereof, pyridine, methylpyridine, pyridine compounds such as 2,6-dimethylpyrimidine and derivatives thereof, aminophenol such as 2-aminophenol and 3-aminophenol and amine compounds such as derivatives thereof. However, the invention is not limited to the above materials.

The inhibition of polymerization by these amine compounds can be of a degree such that the polymerizing reaction does not significantly damage the other portions other than the compatible layer 9 to be described later but does sufficiently reduce the function of the polymerization agent in the compatible layer 9. For this reason, the basic substance and the additive amount of the amine compound being used can be adjusted in order to obtain the target sensitivity and resolution. In particular, a basic substance such as a tertiary amine which is relatively weak is suitably used because the additive amount thereof is easily adjusted.

The additive amount of these basic substances cannot be uniformly set because the additive amount is affected by a degree of the basic substance of the basic substance. However, an additive amount can be set to 0.01 to 20 wt % with respect to the amount of the photo-polymerization initiator which is added to the negative photosensitive resin 8 to be described later, and more preferably, to 0.5 to 4 wt %. When the additive amount of the basic substance is less than 0.01 wt %, polymerization of the compatible layer 9 may be sufficiently inhibited. In addition, when the additive amount of the basic substance exceeds 20 wt %, the other portions excepting the compatible layer 9 may be inhibited from being polymerized. In this case, the exposure amount can be set to cope with the increase thereof, but the exposure takt is reduced, and thus it is not practical in consideration of the productivity. Further, as these basic substances, two or more kinds of mixed materials are useful as long as the balance between various performances is secured.

(Procedure (2))

Next, as illustrated in FIG. 3A, a negative photosensitive resin 8 is coated on a resin film including the positive photosensitive resin 7, and the negative photosensitive resin 8 is compatible with the positive photosensitive resin 7.

The base resin of the negative photosensitive resin 8 in the invention is required to have, by polymerization through light irradiation, a high mechanical strength as an etching material or a structure material, adhesiveness to the base, and solvent resistance in the subsequent procedures. As a material satisfying these characteristics, a cationically polymerizable epoxy resin compound may be employed. As an epoxy resin compound, a reaction product of bisphenol A and epichlorohydrin of which the molecular weight is 900 or more, a reaction product of bromophenol A and epichlorohydrin, a reaction product of phenol novolak or o-cresol novolak and epichlorohydrin, and a polyfunctional epoxy resin having an oxycyclohexane skeleton which is described in Japanese Patent Application Laid-Open No. S64-9216 and Japanese Patent Application Laid-Open No. H02-140219. However, the invention is not limited to these compounds.

In addition, the negative photosensitive resin 8 can be the epoxy resin composition containing a photo-polymerization initiator. As the photo-polymerization initiator contained in the negative photosensitive resin 8, when the base resin of the negative photosensitive resin 8 includes a cationically polymerizable group such as the epoxy resin compound, an aromatic iodonium salt, or an aromatic sulfonium salt is exemplified. Exemplified are “Adekaoptomer SP-170”, “SP-150” (article name) which are made by ADEKA Corporation, “BBI-103”, “BBI-102” (article name) which are made by Midori Kagaku Co., Ltd., “Rhodorsil Photoinitiator 2074” (article name) which is made by Rhodia Ltd., “IBPF”, “IBCF”, “TS-01”, and “TS-91” (article name) which are made by Sanwa Chemical Co., Ltd.

In addition, when the epoxy resin compound which is the base resin of the negative photosensitive resin 8 is a solid, it can be used as a liquid composition which is dissolved by an organic solvent. At this time, as the organic solvent, there is used a solvent which can dissolve the positive photosensitive resin 7. As an organic solvent, polar solvents such as methyl isobutyl ketone, methyl ethyl ketone, cyclohexanone, cyclopentanone, propylene glycol monomethyl ether acetate, propylene glycol monomethylether, diethyleneglycol monomethyl ether, and triethylene glycol dimethyl ether are suitably used. However, the invention is not limited the above solvents.

In addition, the amount of the negative photosensitive resin 8 to be coated is calculated from a volume of the mold 3 to be filled which is described later and it can be a suitable amount.

Further, when the base resin of the negative photosensitive resin 8 is a solid and is coated on the resin film including the positive photosensitive resin 7 as the liquid composition which is dissolved in the solvent, compatibility is not caused between both resins solely by coating, but the compatible layer is formed by pressing and heating with the mold to be described. In addition, even when the base resin of the negative photosensitive resin 8 is a liquid and the solvent is not used, the compatible layer is similarly formed by pressing and heating with the mold to be described.

(Procedure (3))

Next, as illustrated in FIG. 3B, the mold 3 on which the pattern is formed is pressed against the negative photosensitive resin 8, so that the positive photosensitive resin 7 and the negative photosensitive resin 8 disposed in a gap between a convex portion 3a of the pattern of the mold 3 and the quartz substrate 6 are totally compatibilized so as to form the compatible layer 9.

When the substrate provided with the resin film including the positive photosensitive resin 7 is an opaque substrate instead of a transparent substrate such as the quartz substrate, a mold including a transparent material is used as the mold 3 used in the invention. In this case, the material can be one that has transparency and strength along with the required workability accuracy, such as quartz, glass, ceramic, plastic, or photosensitive resin. However, the invention is not limited to these materials. In addition, as in this embodiment, when the substrate is provided with the resin film including the positive photosensitive resin 7, various materials, such as silicon, various kinds of metallic materials, glass, ceramic, plastic, or the like, can be employed as long as the strength and the workability are excellent. However, the invention is not limited to the exemplified materials. Furthermore, the shape of the mold 3 is not particularly limited, but it is a matter of course that a concave-convex shape may be formed in many steps.

In the invention, the mold 3 is pressed against the negative photosensitive resin 8, so that the compatible layer 9 is formed which is in a state where two resins are compatibilized and mixed in the boundary portion between the positive photosensitive resin 7 and the negative photosensitive resin 8. Since the compatible layer 9 is pressed by the mold 3 on which the pattern is formed, a compatible region is expanded by the pressure. In particular, in the region (which corresponds to a portion which is the residue in a typical imprint process) with a small thickness of the negative photosensitive resin 8 in the gap between the convex portion of the pattern of the mold 3 and the quartz substrate 6, the entire negative photosensitive resin 8 can be compatibilized with the positive photosensitive resin 7.

In the compatible layer 9 in which the positive photosensitive resin 7 and the negative photosensitive resin 8 are compatibilized, a curing reaction rate at the time of being irradiated with the active energy ray is reduced, and a crosslink reaction is unlikely to proceed more than normal because a molecular density of the negative photosensitive resin 8 is reduced by compatibility. On the other hand, since the molecular weight of the positive photosensitive resin 7 becomes small by being irradiated with the active energy ray so as to be changed to be easily dissolved in the developer, the compatible layer 9 on which the active energy ray is irradiated is dissolved relatively easily in the developer. For this reason, the residue which has been a problem in the imprint method can be dissolved and removed by the developer. At this time, when the basic substance is added to the positive photosensitive resin 7 as described above, the cure reaction of the negative photosensitive resin 8 in the compatible layer 9 can be inhibited. Therefore, the solubility to the developer of the compatible layer 9 is further increased.

As for the conditions when the mold 3 is pressed against the negative photosensitive resin 8, the temperature of the quartz substrate 6 is 60 to 150° C., and the pressure when the mold 3 is pressed is 0.01 to 10 MPa, because the compatible layer 9 is thus easily formed.

In addition, in order to improve the peelability, after the mold 3 is dipped into a mold release agent so as to be subjected to the releasing process, the mold 3 is rinsed by a rinse agent and the mold release agent is removed.

(Procedure (4))

Next, as illustrated in FIG. 3C, in a state where the mold 3 is pressed against the negative photosensitive resin 8, the negative photosensitive resin 8 and the positive photosensitive resin 7 are irradiated by the active energy ray over the entire surface through the quartz substrate 6. Therefore, the negative photosensitive resin 8 is cured, and the positive photosensitive resin 7 and the compatible layer 9 are solubilized with respect to the developer.

In the invention, the positive photosensitive resin 7 and the negative photosensitive resin 8 absorb exposure light from each other, so that there is a need to note that the reaction is not inhibited. For this reason, an exposure apparatus may suitably use an exposure device of a lamp having a broad wavelength such as a mercury lamp instead of using an exposure device of a bright line such as an i-ray stepper or a g-ray stepper.

In this embodiment, the active energy ray is irradiated through the quartz substrate 6. However, when a mold made of a transparent material such as a quartz mold is employed as the mold 3, the active energy ray may be irradiated through the mold.

In addition, in the invention, in order to accelerate the curing of the negative photosensitive resin 8, a heating process may be carried out after the active energy ray is irradiated.

(Procedure (5))

Next, as illustrated in FIG. 3D, the mold 3 is released and the pattern is formed on the negative photosensitive resin 8. Thereafter, as illustrated in FIG. 3E, the negative photosensitive resin 8 on which the pattern is formed is attached on another support substrate 18.

As this another support substrate 18, the material can be transparent and have strength along with the required workability accuracy, such as quartz, glass, ceramic, plastic, photosensitive resin. However, the invention is not limited to these materials.

(Procedure (6))

Next, only the quartz substrate 6 of the quartz substrate 6 provided with the resin film including the positive photosensitive resin 7 is peeled off from the positive photosensitive resin 7 and the compatible layer 9.

The peeling of the quartz substrate 6 can be carried out such that the quartz substrate 6 is heated after the attachment in Procedure (5) is carried out, and the low-molecular positive photosensitive resin 7 is dried by being irradiated with the active energy ray in Procedure (4).

(Procedure (7))

Next, the positive photosensitive resin 7 and the compatible layer 9 are developed and removed by the developer.

As a developer to be used for development removal, propylene glycol monomethyl ether acetate, methyl isobutyl ketone, or the like may be used. The invention is not limited to the above developer as long as the compatible layer 9 and the positive photosensitive resin 7 can be dissolved. In addition, after the developer is developed, a rinse treatment may be carried out using isopropyl alcohol (IPA) or the like.

Through the above-mentioned process, as illustrated in FIG. 3F, a desired pattern without residue can be obtained.

[Manufacturing Method of Ink Jet Head]

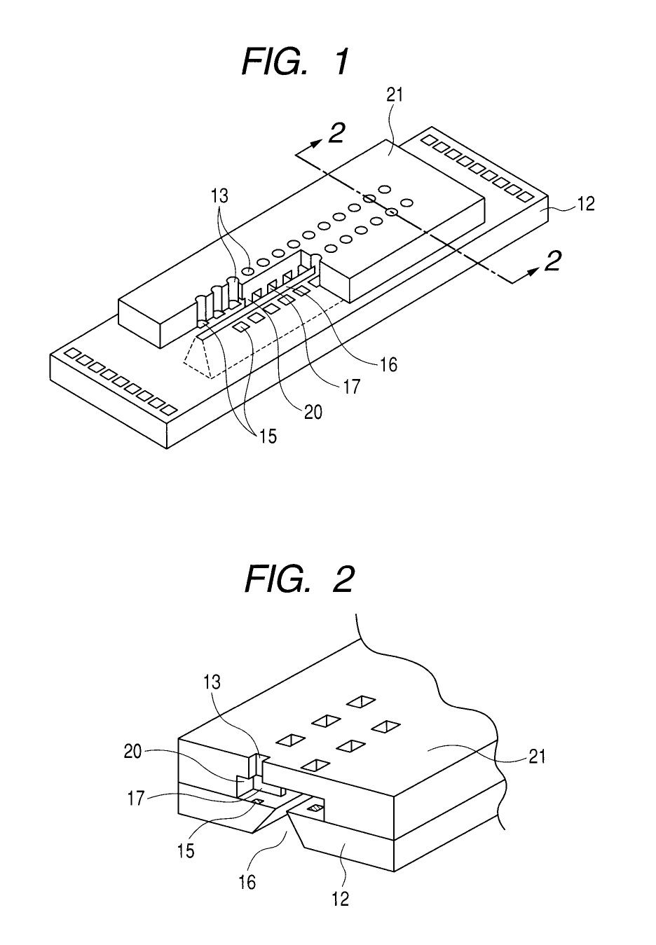

FIG. 2 illustrates a diagram schematically illustrating a cross section of an example of the ink jet head which is manufactured by the manufacturing method of the ink jet head according to the invention. FIG. 2 illustrates the diagram taken along the boundary line 2-2 of FIG. 1.

In FIG. 2, an ink supply port 16 which supplies ink to an ink flow path 17 is formed in a substrate 12 provided with a heater element 15 as an element which generates energy to be used to discharge a liquid. In addition, on the substrate 12 provided with the heater element 15, an ink discharge port 13 and a nozzle plate in which the ink flow path 17 is formed to communicate with the ink discharge port 13 are provided.

In the above-mentioned configuration, ink is supplied and held to the ink flow path 17 from the ink supply port 16. The heater element 15 is supplied with electricity according to a recording signal, so that bubbles are instantaneously generated in the supplied ink by thermal energy which is converted by the heater element 15. As the bubbles grow, pressure increases and is changed. Using the pressure, an ink droplet is discharged from the ink discharge port 13 so as to be recorded to a recording medium.

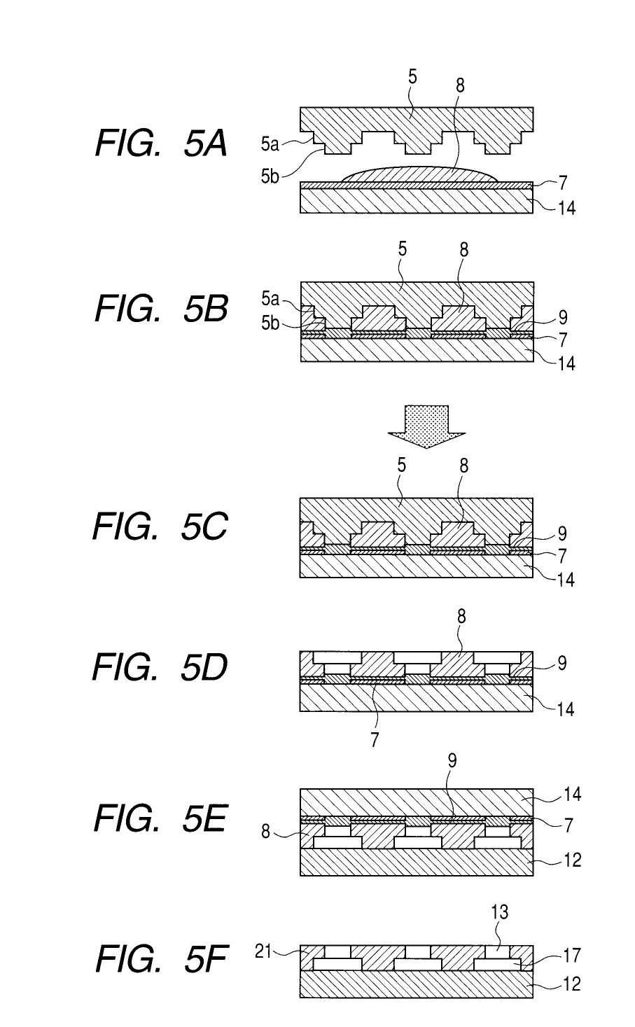

FIGS. 5A to 5F illustrate an example of an embodiment of the manufacturing method of the ink jet head according to the invention. Further, the invention is not limited to the following embodiment.

In this embodiment, a silicon substrate 14 is first prepared. On the prepared silicon substrate 14, the positive photosensitive resin 7 is coated similarly to the forming method of the fine pattern.

Next, as illustrated in FIG. 5A, a predetermined amount of the negative photosensitive resin 8 is dispensed to the silicon substrate 14 coated with the positive photosensitive resin 7.

Next, as illustrated in FIG. 5B, the prepared quartz mold 5 is pressed against the negative photosensitive resin 8. In this embodiment, the quartz mold 5 with steps each having two stages is used as a mold. However, in order to form a desired ink flow path and a desired ink discharge port, the shape of the mold may be different from that in this embodiment. The materials of the positive photosensitive resin 7 and the negative photosensitive resin 8 to be used, and the conditions when pressing may be similar to the forming method of the fine pattern. Therefore, the positive photosensitive resin 7 and the negative photosensitive resin 8 which are in the gap between the convex portion corresponding to the ink discharge port of the quartz mold 5 and the silicon substrate 14 are totally compatibilized so as to be the compatible layer 9.

Next, as illustrated in FIG. 5C, the active energy ray is irradiated on the entire surface through the quartz mold 5 in a state where the quartz mold 5 is pressed against the negative photosensitive resin 8, so that the negative photosensitive resin 8 is cured and the positive photosensitive resin 7 and the compatible layer 9 are dissolved in the developer. The exposure device and the irradiating conditions of the energy ray may be similar to those of the forming method of the fine pattern.

Next, as illustrated in FIG. 5D, the quartz mold is released, and a pattern is formed on the negative photosensitive resin 8. Thereafter, as illustrated in FIG. 5E, the negative photosensitive resin 8 on which the pattern is formed is attached to the substrate 12 provided with the heater element. The conditions at the time of attachment may be similar to those of the forming method of the fine pattern.

Next, only the silicon substrate 14 is peeled off from the positive photosensitive resin 7 and the compatible layer 9. The positive photosensitive resin 7 and the compatible layer 9 are developed by the developer so as to be removed. The peeling of the silicon substrate 14 and the conditions of developing and removing the positive photosensitive resin 7 and the compatible layer 9 may be similar to those of the forming method of the fine pattern.

Through the above-mentioned procedures, as illustrated in FIG. 5F, it is possible to obtain the ink jet head which is provided with the ink flow path 17 and the ink discharge port 13 with a desired shape having no residue.

### EXAMPLES

### Example 1

FIGS. 3A to 3F illustrate the fine pattern manufacturing method according to Example 1. First, in this example, the quartz substrate 6 was prepared.

As illustrated in FIG. 3A, the prepared quartz substrate 6 was coated to be formed with a thickness of 1 μm using a resin which was made by adding 1.0 wt % of triethanolamine to a copolymer of methacrylic acid and methyl methacrylate (methyl methacrylate:methacrylic acid=90:10, Mw=80000, Mn=2.5) as the positive photosensitive resin 7 with respect to the copolymer resin of methacrylic acid and ethyl methacrylate.

Next, as the negative photosensitive resin 8, “SU-8 3005” (article name) which is made by Kayaku Microchem Corporation. was prepared, and a nickel mold with a depth of 5 μm having a desired pattern was prepared as the mold 3.

As illustrated in FIG. 3A, on the quartz substrate 6 coated with the positive photosensitive resin 7, a predetermined amount of “SU-8 3005” of the negative photosensitive resin 8 was dispensed.

Thereafter, as illustrated in FIG. 3B, the prepared mold 3 was pressed against the negative photosensitive resin 8. As for the conditions when the mold 3 was pressed, the temperature of the quartz substrate was 40° C., and the pressure was 0.2 MPa, so that the compatible layer 9 was easily formed by heat and pressure. Therefore, the positive photosensitive resin 7 and the negative photosensitive resin 8 between the convex portion of the mold 3 applied with pressure and the quartz substrate 6 were totally compatibilized so as to form the compatible layer 9. Further, the amount of the dispensed negative photosensitive resin 8 was calculated from the volume of the filled side of the mold 3 so as to drop a suitable amount of the resin. In addition, the mold 3 was used which was dipped into “DURASURF HD-1101TH” (article name) which is the mold release agent made by Harves Co., Ltd. so as to be subjected to a releasing process. After being left at room temperature for 24 hours, the mold 3 was rinsed with “Novec HFE-7100” (article name) which is made by Sumitomo 3M Ltd., and the releaser was removed.

Subsequently, as illustrated in FIG. 3C, an ultraviolet ray was irradiated from the surface of the quartz substrate 6 in a state where the mold 3 was being pressed, and then the mold 3 was heated at 95° C. for 6 min, so that the curing of the negative photosensitive resin 8 and the dissolution of the positive photosensitive resin 7 and the compatible layer 9 to the developer were carried out. The exposure device used at this time was a mask aligner “MPA 600” (article name) made by Canon Inc., and the amount of the irradiating ultraviolet ray was 300 mJ/cm². Thereafter, as illustrated in FIG. 3D, the mold 3 was released so as to form a desired pattern on the negative photosensitive resin 8.

Next, as illustrated in FIG. 3E, the negative photosensitive resin 8 on which the pattern was formed was attached to a target support substrate 18. As the support substrate 18, a 6 inch wafer was used. As for the conditions of attachment, the support substrate 18 was applied with force of 20 kN at room temperature so as to be attached.

Thereafter, the quartz substrate 6 was heated, and the low-molecular positive photosensitive resin 7 was dried by irradiation with the ultraviolet ray. Therefore, the quartz substrate 6 was peeled off from the positive photosensitive resin 7 and the compatible layer 9. Thereafter, the positive photosensitive resin 7 and the compatible layer 9 were developed by propylene glycol monomethyl ether acetate, and were rinsed by IPA, so that a desired imprint pattern without a residue was obtained.

### Example 2

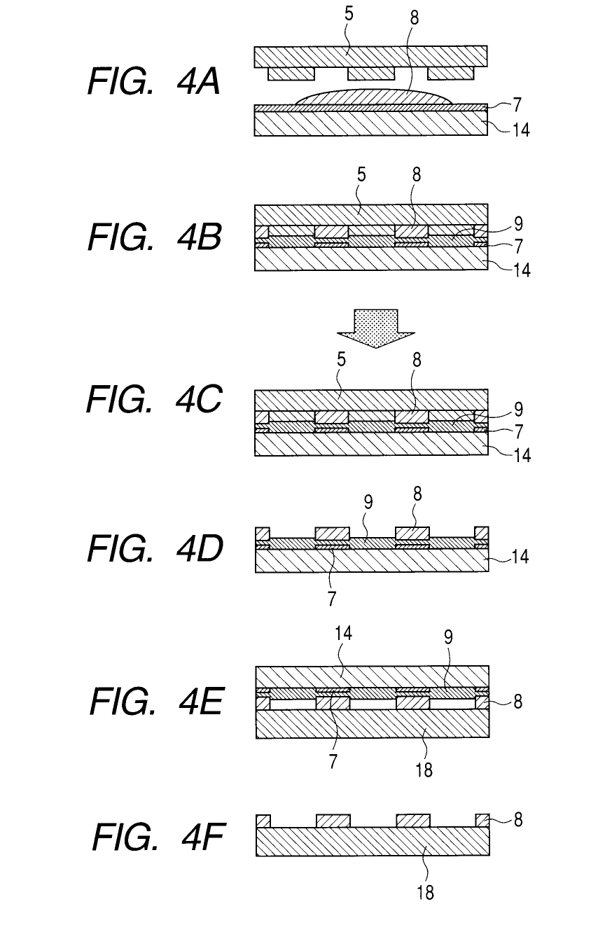

FIGS. 4A to 4F illustrate the fine pattern manufacturing method according to Example 2. First, in this example, the silicon substrate 14 was prepared.

As illustrated in FIG. 4A, the prepared silicon substrate 14 was coated to be formed with a thickness of 0.5 μm using a resin which is made by adding 0.5 wt % of triethanolamine to a copolymer of methacrylic acid and methyl methacrylate (methyl methacrylate:methacrylic acid=70:30, Mw=100000, Mn=2.0) as the positive photosensitive resin 7 with respect to the copolymer resin of methacrylic acid and ethyl methacrylate.

Next, as the negative photosensitive resin 8, “TMMR 2000” (article name) which is made by Tokyo Ohka Kogyo Co., Ltd. was prepared, and a quartz mold 5 with a depth of 10 μm having a desired pattern was prepared as the mold.

As illustrated in FIG. 4A, on the substrate coated with the positive photosensitive resin 7, a predetermined amount of “TMMR 2000” of the negative photosensitive resin 8 was dispensed.

Thereafter, as illustrated in FIG. 4B, the prepared quartz mold 5 was pressed against the negative photosensitive resin 8. As for the conditions when the quartz mold 5 was pressed, the temperature of the silicon substrate 14 was 40° C., and the pressure was 0.2 MPa, so that the compatible layer 9 was easily formed by heat and pressure. Therefore, the positive photosensitive resin 7 and the negative photosensitive resin 8 between the convex portion of the quartz mold 5 applied with pressure and the silicon substrate 14 were totally compatibilized so as to form the compatible layer 9. Further, the amount of the dispensing negative photosensitive resin 8 was calculated from the volume of the filled side of the quartz mold 5 so as to dispense a suitable amount of the resin. In addition, the quartz mold 5 was subjected to the releasing process similar to the method of Example 1.

Subsequently, as illustrated in FIG. 4C, a ultraviolet ray was irradiated from the quartz mold 5 side in a state where the quartz mold 5 was being pressed, and then the mold 5 was heated at 90° C. for 5 min, so that the curing of the negative photosensitive resin 8 and dissolution of the positive photosensitive resin 7 and the compatible layer 9 to the developer were carried out. The exposure device used at this time was “MPA 600”, and the amount of the irradiating ultraviolet ray was 150 mJ/cm². Thereafter, as illustrated in FIG. 4D, the quartz mold 5 was released so as to form a desired pattern on the negative photosensitive resin 8.

Next, as illustrated in FIG. 4E, the target support substrate 18 was transferred by the same method as that in Example 1. Thereafter, the silicon substrate 14 was peeled off from the positive photosensitive resin 7 and the compatible layer 9, the positive photosensitive resin 7 and the compatible layer 9 were developed and removed, and rinsing was carried out, so that a desired imprint pattern without a residue was obtained as illustrated in FIG. 4F.

### Example 3

FIGS. 5A to 5F illustrate the manufacturing method of the ink jet head according to Example 3. First, in Example 3, the silicon substrate 14 was prepared.

As illustrated in FIG. 5A, the prepared silicon substrate 14 was coated to be formed with a thickness of 0.5 μm using a resin which was made by adding 0.5 wt % of triethanolamine to a copolymer of methacrylic acid and methyl methacrylate (methyl methacrylate:methacrylic acid=90:10, Mw=100000, Mn=2.0) as the positive photosensitive resin 7 with respect to the copolymer resin of methacrylic acid and ethyl methacrylate.

Next, as the negative photosensitive resin 8, “TMMR 2000” (article name) which is made by Tokyo Ohka Kogyo Co., Ltd. was prepared, and a quartz mold 5 with a depth of 20 μm having a desired pattern was prepared as the mold. As illustrated in FIG. 5A, the quartz mold 5 was a quartz mold with steps each having two stages configured of two convex portions 5a and 5b. The depth of one step was 10 μm. The quartz mold 5a was provided in a region of the quartz mold 5b.

As illustrated in FIG. 5A, on the substrate coated with the positive photosensitive resin 7, a predetermined amount of “TMMR 2000” of the negative photosensitive resin 8 was dispensed.

Thereafter, as illustrated in FIG. 5B, the prepared quartz mold 5 was pressed against the negative photosensitive resin 8. As for the conditions when the quartz mold 5 was pressed, the temperature of the silicon substrate 14 was 40° C., and the pressure was 0.2 MPa, so that the compatible layer 9 was easily formed by heat and pressure. Therefore, the positive photosensitive resin 7 and the negative photosensitive resin 8 between the convex portion of the quartz mold 5 applied with pressure and the silicon substrate 14 were totally compatibilized so as to form the compatible layer 9. Further, the amount of the dispensing negative photosensitive resin 8 was calculated from the volume of the filled side of the quartz mold 5 so as to dispense a suitable amount of the resin. In addition, the quartz mold 5 was subjected to the releasing process similar to the method of Example 1.

Subsequently, as illustrated in FIG. 5C, a ultraviolet ray was irradiated from the quartz mold 5 in a state where the quartz mold 5 was being pressed, and then the mold 5 was heated at 90° C. for 5 min, so that the curing of the negative photosensitive resin 8 and dissolution of the positive photosensitive resin 7 and the compatible layer 9 to the developer were carried out. The exposure device used at this time was “MPA 600”, and the amount of the irradiating ultraviolet ray was 150 mJ/cm². Thereafter, as illustrated in FIG. 5D, the quartz mold 5 was released so as to form a desired pattern on the negative photosensitive resin 8.

Next, as illustrated in FIG. 5E, the substrate 12 provided with the heater element was transferred by the same method as that in Example 1. The silicon substrate 14 was peeled off from the positive photosensitive resin 7 and the compatible layer 9. Thereafter, the positive photosensitive resin 7 and the compatible layer 9 were developed and removed, and rinsing was carried out, so that a desired ink jet head without a residue was obtained as illustrated in FIG. 5F.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-323675, filed Dec. 19, 2008, which is hereby incorporated by reference herein in its entirety.

What is claimed is:

1. A method of manufacturing a structure comprising:
(1) preparing a substrate which is provided with a resin film including a positive photosensitive resin on a surface thereof;
(2) coating a negative photosensitive resin, which is compatible with the positive photosensitive resin, on the resin film including the positive photosensitive resin;
(3) pressing a mold formed with a pattern against the negative photosensitive resin, and compatibilizing the positive photosensitive resin and the negative photosensitive resin which are provided in a gap between a convex portion of the pattern of the mold and the substrate, to form a compatible layer;
(4) irradiating the entire surface of the negative photosensitive resin and the positive photosensitive resin with an active energy ray through the substrate or the mold in a state where the mold is pressed against the negative photosensitive resin to cure the negative photosensitive resin, and solubilizing the positive photosensitive resin and the compatible layer with respect to a developer;
(5) releasing the mold, forming a pattern on the negative photosensitive resin, and attaching the negative photosensitive resin formed with the pattern to another support substrate;
(6) peeling off only the substrate of the substrate provided with the resin film including the positive photosensitive resin from the positive photosensitive resin and the compatible layer; and
(7) removing the positive photosensitive resin and the compatible layer by a developer.

2. The method of manufacturing a structure according to claim 1,
wherein a base resin of the negative photosensitive resin is a liquid.

3. The method of manufacturing a structure according to claim 1,
wherein the negative photosensitive resin is a liquid composition in which a solid base resin is dissolved in a solvent which dissolves the positive photosensitive resin.

4. The method of manufacturing a structure according to claim 1, wherein the negative photosensitive resin is an epoxy resin composition containing a photo-polymerization initiator.

5. The method of manufacturing a structure according to claim 1, wherein the positive photosensitive resin contains a basic substance.

6. The method of manufacturing a structure according to claim 1, wherein an amount of a basic substance contained in the positive photosensitive resin is 0.01 to wt % with respect to an amount of the photo-polymerization initiator which is contained in the negative photosensitive resin.

7. A method of manufacturing an ink jet head including an ink flow path communicating with a discharge port for discharging ink, the method comprising:
preparing a substrate which is provided with an energy generating element which generates energy used for discharging a liquid; and
providing a structure on the substrate, the structure being obtained by the method of manufacturing the structure according to claim 1.
